(19) United States
(12) Patent Application Publication
(10) Pub. No.: US 2011/0305494 A1
(43) Pub. Date: Dec. 15, 2011

(54) PORTABLE AND EASE-OF-USE ERGONOMIC KEYBOARD

(76) Inventor: Chulho Kang, San Ramon, CA (US)

(21) Appl. No.: 12/813,709

(22) Filed: Jun. 11, 2010

(51) Int. Cl. B41J 5/00; H05K 13/00

(52) U.S. Cl. 400/489; 29/592.1

(57) ABSTRACT

The present invention provides a portable and easier to use three-dimensional keyboard for computer-type devices. In a preferred embodiment, the keyboard of the present invention includes smaller keys for select character, functional and operational keys, select raised keys and a keyboard that is more ergonomic and easier to use with smaller computer-type devices. Such embodiments of the present invention provide a simple, improved ergonomic keyboard that is portable, easier-to-use, ergonomic and is compatible with the QWERTY keyboard.

### FIELD OF THE INVENTION

The present invention relates to computer input devices and, more particularly, to ergonomic keyboards that are portable and easier to use than conventional keyboards.

### BACKGROUND OF THE INVENTION

The present invention relates to an ergonomic keyboard that is portable and easier to use. In particular, the present invention is a three-dimensional keyboard that allows the operator to keep their hands and fingers on the home row while easily finding other frequently-used and important character, operational and/or functional keys.

The conventional keyboard known as the QWERTY keyboard is a legacy of the manual typewriter invented a century ago. The arrangement of its characters, operational and function keys was fixed long before the present day innovations such as touch pads, laptops and mobile devices. As a result, the conventional keyboard suffers from numerous shortcomings. For example, its arrangement of character letters does not account for letter frequencies. Furthermore, it ignores anatomic differences of the strength and positioning in human fingers and hands.

On the conventional keyboard for example, the left hand executes more strokes and complex finger motions than the right hand. Most stroking sequences are performed by fingers of the same hand because common vowels and consonants are allotted to the same hand. The middle row is not a true home row because more frequently used keys occur on the top row rather that the middle row. The horizontal straight key rows consist of keys staggered on different rows that do not fit the hand. The flat or nearly-flat keyboard ignore differences in finger length and strength. The weak pinky fingers for example must operate many operational and functional keys on the periphery of the keyboard.

Furthermore, some frequently-used keys on the conventional QWERTY keyboard require significant reach to strike them, while some less-frequently used keys are easily reached. In general, it is difficult for novice typists to learn the QWERTY keyboard and, in most cases, a significant amount of training and continuous practice is necessary to reach and maintain a high level of speed and accuracy.

As shown in FIG. 1A, conventional keyboards compound these problems by introducing a large number of additional keys, such as function keys, numeric entry keys, and cursor positioning keys. On a conventional keyboard, the total number of keys can reach a hundred. Additionally, the size of these keyboards can reach widths of 40 cm or more. As a result, the difficulty of remembering the precise location of each key on various types of computer devices encountered on a daily basis (PDA's, cell phones, laptops) makes the matter worse. The result of all these shortcomings is reduced typing speed and accuracy. In response, various attempts have been made to devise improved keyboards to increase typing speeds and/or decrease typing errors.

The prior art is replete with references to correct these deficiencies. Some have split the keyboard. Others have curved the key rows to fit the hand. A few suggest variable height keys and others have suggested moving operational and functional keys to the center of the keyboard operated by the thumb. There have been a few that suggest keys slanted or oriented toward the home row. There are many suggestions to increase the size of keys for letters of the most-commonly used letters and reduce the size of seldom-used letters.

Most notably, there have numerous attempts at changing the QWERTY key arrangement. The best attempt was by Dvorak and Dealey in U.S. Pat. No. 2,040,248 where they applied linguistic statistics to maximize successive strokes by alternate hands and minimize successive strokes by the same finger. Briefly, they place the frequently-used keys directly under the user's strongest and closest fingers such as the index fingers, and the less-frequently-used keys under the user's weakest fingers, such as the pinky or ring finger. Although successful in lowering mistakes and increasing speed, they retained the same special configuration with staggered keys in adjacent rows and controls at the corners of the keyboard.

Others have assigned multiple characters to individual keys, thereby reducing the total number of keys. With some keyboards, a character is pressed a particular way such as pressing the corner, or by repeating pressing a particular key a different number of times in order to find the correct key. Some schemes employ algorithms to predict which character the user wishes to type.

All of these alternative layouts have the disadvantage that they do not retain the QWERTY keyboard that so many users have become accustomed. Over the years, typists have been trained on the QWERTY keyboard resulting in a dominant base of users who can in fact type quickly and accurately. Furthermore, organizations and individuals who have invested a significant amount of resources are not going to change within the near future. As a result, new computer-type devices having a QWERTY style keyboard are likely more acceptable than one with a different layout. In fact, none of the alternative layouts described in the prior art has met any success due in part from the dominance of the QWERTY keyboard and its widespread acceptance.

As computer-type devices become smaller and more widely used, there is a need for a simple and improved ergonomic keyboard that is portable, easier-to-use but is compatible with the QWERTY keyboard. It is an object of the present invention to provide a simple, improved ergonomic keyboard that consists of various embodiments that make it portable, easier-to-use and is compatible with the QWERTY keyboard.

Now referring to drawings, FIG. 8 illustrates how the present invention overcomes many of the shortcomings of the conventional keyboard while maintaining the QWERTY keyboard. By understanding the prior art keyboards and the conventional keyboard shown in FIG. 8A, one can appreciate an important advantage of an embodiment of present invention. As shown in FIG. 8B, the scale advantage of the present invention over the conventional keyboard is obvious. The present invention in FIG. 8B is approximately half the size of a conventional keyboard making it more portable for present day computer-type devices including laptops, Personal Digital Assistants (PDA), notebooks and cell phones. Whereas a conventional keyboard is approximately 30 cm or greater, the present invention may be approximately 20 cm or smaller in horizontal width An another embodiment of the present invention is a three-dimensional keyboard that improves the ergonomics of the conventional keyboard. By permitting differences in keys heights between select character, functional and operational keys shown in FIG. 5B, the three-dimensional embodiment is more ergonomic for human fingers and hands. Such an embodiment is made possible by the “key bump” shown in FIG. 5B. In addition to creating three-dimensional spacing, the “key bump” creates three other embodiments. First, it permits natural home row positioning (FIG. 7B) and second, provides tactile key recognition (FIG. 6B). While the fingers and hands move off the home row to strike other keys the fingers can recognize targeted keys and then return easily to the natural home row position. By contrast, the conventional keyboard shown in FIG. 1A remains flat or nearly flat. Along with the three-dimensional embodiment, key size differences shown in FIG. 3B permit greater dexterity for either the encumbered or unencumbered fingers shown in FIG. 2. Such key size difference takes advantage and compensates for the varying finger strengths and lengths that are naturally occur human fingers and hands. Taken all together, these present invention embodiments make a more portable, easier-to-use and ergonomic keyboard.

Now referring to FIG. 1A, a conventional keyboard 100 used on many computer-type devices is shown (not a part of the present invention). Such a keyboard 100 is in a flat or nearly flat horizontally planar surface with a plurality of character keys. The alphanumeric character keys are generally square, flat and arranged in an array commonly known as QWERTY. These keys are arranged in straight and transversely disposed rows including a home row 102, an upper row 104 and a lower row 106. On a conventional keyboard, the alphanumeric keys are about 2 cm in width and are all uniform in size and spacing. Most character keys are separated by a space or distance that is equal to the size of character keys (i.e., the distance from the middle of one key to the middle of another is 2 cm. Overall, the conventional keyboard can easily reach lengths of greater than 25 cm.

The conventional keyboard shown in FIG. 1A further includes a numerical lateral row 108 above the second character row and function-controls keys 110 above the numerical row 108. There are also many laterally staggered side and bottom functional keys 112 with respect to the adjacent character rows including lateral cursor keys 114. The size of many non-alpha-numeric keys is based on frequency of use. The SPACE bar 116, for example, is the most commonly used, largest key and can be about 10 cm in length. Function-control keys may vary in size from smaller (˜2.5 cm) to greater (˜4 cm) than the character keys. Similarly, the SHIFT, BACKSPACE and ENTER keys which are used frequently, are also typically larger than alphanumeric keys. In total, there can be more than 75 character and/or functional keys on a conventional keyboard. On some keyboards, there can also be small protrusions or scratches 118 on the F and J keys to help position the hands on the home row. Without going into detail, the modern conventional or universal keyboard used widely today is almost identical to the manual typewriter invented a century ago.

A pair of hands 120, 122 in FIG. 1B with its fingers and thumbs (124-140) is shown resting on QWERTY's keyboard home row (not a part of the present invention). The QWERTY keyboard however was not designed to do most of typing on the home row. Only 32 percent of strokes for example are on the home row 102; most strokes (52 percent) are on the upper row 104; and a full 16 percent are on the lower row 106. The home row 102 of nine letters includes two of the least used (7 and K) but none of the three most frequently used (E, T, and 0, which are relegated to the upper row 104) and only one of the five vowels (A), even though 40 percent of all letters in a typical English text are vowels. At times, the fingers must not Only reach from the home row 102 to the upper row 104 or lower row 106 and but also may have to travel completely over the home row, moving directly from upper to the lower row and back again. A good example is the DELETE key 144. The DELETE key 144 is a frequently used key but one of the weakest fingers (right pinky) 132 has to travel over 6 cm to reach it 126. To reach the alphanumeric top row 104 or the bottom row, the fingers must travel almost 4 cm 146 to do so. Such distance slows the operator, introduces typing errors and causes finger strain. Obviously, an operator can do more typing when their fingers don't have to move from the home row. In general, the faster an operator is able to type, the fewer errors they will make, and the less one will strain their fingers.

Another legacy of the manual typewriter in FIG. 1A is the functions of the ENTER/RETURN, SHIFT, CAPS LOCK and DELETE/BACKSPACE keys. On the manual typewriter, the ENTER/RETURN key 115 either changed or forwarded the line for typing additional text. Traditionally, a carriage-return lever performed the same function. The typist could for example change the typing line by pushing and moving the carriage return lever simultaneously by the left hand. On a modern conventional keyboard, the ENTER/RETURN key is now used for the same function as the carriage return lever but is now located on the right side and is performed by the weaker right pinky finger 132. On modern word processors with wrap-around function, the carriage no longer has to “return” to its starting position.

A significant innovation on the manual typewriter was the SHIFT key. This key physically “shifted” either the basket of type bars, in which case the typewriter is described as “basket shift”, or the whole carriage, in which case the typewriter shifted its “carriage” to type capitalize letters. However, because the SHIFT key required more force to push (its mechanism was moving a much larger mass than other keys), and was operated by the “pinky” finger (normally the weakest finger on the hand), it was difficult to hold the SHIFT down for more than two or three consecutive strokes. The “SHIFT LOCK” key (the precursor to the modern CAPS LOCK) allowed the shift operation to be maintained indefinitely. Unlike the today's CAPS LOCK, however, the SHIFT LOCK was a two-key operation: SHIFT would be held down, and the SHIFT LOCK (normally directly above) would be pressed simultaneously, triggering a simple lock mechanism. To unlock, SHIFT was tapped again, releasing both keys and un-shifting the basket. To do so, it was necessary to have two SHIFT keys 112 on either side of the keyboard. In some cases, the carriage could be so heavy to lift by the one pinky finger alone that two pinky fingers may have been required. On the modern conventional keyboard, there are still two SHIFT keys 112 on both the left and right sides of the keyboard that are remnants of the manual typewriter. Such two SHIFT keys 112 take up valuable real estate on the keyboard and can be re-positioned elsewhere. The CAPS LOCK key 113 now performs the same function.

One of the most important keys is the DELETE/BACKSPACE key 144. It is unfortunately positioned at the far upper right and is one of the most distanced keys from the home row. To reach it, the right hand must remove itself from the home row to push it. It too can be re-positioned.

FIG. 1B also shows another shortcoming of the QWERTY keyboard the distribution of letter disregards the variations in letter frequencies and strength of individual fingers. On the conventional keyboard, the left hand 120 executes more strokes and completes more complex fingers motions than the agile right hand 122. For example, the fingers on the same hand make many intricate strokes because many common vowels and consonants are allotted to the same hand. As such, the home row 102 is not a true home row because more strokes occur on the top letter row than on the middle. Furthermore, the straight keys staggered on different rows do not fit the hand. Additionally, such horizontal flat planar keys ignore differences in finger length—and the weak little fingers must operate shift and control keys at the edges of the keyboard.

Whenever the left 120 and right 122 hands type alternate letters, one hand has to get into position for the next letter while the other hand is typing the previous one. In doing so, the hands frequently lose their home position. On some conventional keyboards, there are slightly raised and small protrusions 118 (shown in FIG. 1A) to help start off or return back to the home row. Whereas an operator is supposed to fall into a steady rhythm and type quickly, a good typist's speed is seldom steadily maintained. Typists repeatedly shifts between fast bursts and slow stutters within even a few seconds, and many of the stutters arise from strings of consecutive letters typed by the same hand. When doing so, many operator hands quickly lose their home position. When so, the typist has to look at the home row or feel for the small protrusions 118 (if available) to help reposition their hands on the home row. The longer the string, the slower the typing rate and more frequent the errors. In most cases, such scratches or protrusions are too small to be effective.

As mentioned, the QWERTY keyboard generates long one-handed strings of letters, especially strings for the weak left hand 120. More than 3,000 English words utilize QWERTY's left hand alone, and about 300 the right hand. The reason for this shortcoming is that most English syllables contain both vowels and consonants, but QWERTY keyboard assigns some vowels (A and E) as well as some common consonants (R, S, and D) to the left hand 120, and others (I, O, and U, plus H, L, and N) to the right hand 122. Hence, for about half of all digraphs (two consecutive letters) in a typical English text, the QWERTY keyboard allocates both letters to the left hand 120. In a study of digraphs or two-letter sequences commonly found in printed text, such as rt, tr, ed, de, fr, sw, ty, gy, are typed by the same finger and most prominently the left index finger 136 and left middle finger 138 resulting in a decrease in typing speed.

Another shortcoming shown in FIG. 1B is when both thumbs on both hands 124, 134 are positioned solely on or over the SPACE bar 116. The two thumbs are therefore devoted to perform only one function that is, character spacing. As a result, the thumbs are under-utilized and the versatility of the thumb is not realized from conventional keyboard. Due to its size as largest key, the SPACE bar therefore uses and wastes a considerable amount of keyboard space.

An outline of the hands shown in FIG. 1B is overlaid in the home row typing position in FIG. 2 (not part of the present invention). To help illustrate the fingers, the conventional digit numbering system of the hands is shown (1, 2, 3, 4, 5). This figure illustrates how the QWERTY keyboard allocates major keys to the weaker left hand 138. This includes the most common English letter (E), the second most common (T), and the fourth most common (A), thus making the left hand 138 perform more than half of all typing strokes (56 percent). The QWERTY keyboard overuse of our weaker hand also extends to our weaker fingers. On each hand, the pinky (fifth finger) 132, 142 is the weakest finger. In contrast, finger strength increases from the fifth to the second finger (index finger) 126, 136. Yet QWERTY makes almost as much use of our weakest finger (left fifth) 132 as of our second strongest (right third) 128.

The QWERTY keyboard arrangement also produces awkward finger sequences. For example, keys strokes that alternate between hands are faster than successive strokes of the same hand. But typing two successive strokes with the same hand is fastest with two remote fingers (such as at, left fifth 142 to second finger 136), next fastest with two adjacent fingers (as, left fifth 142 to fourth finger 140), slower with the same finger on the same row (i.e., left third finger 138), and slowest of all with the same finger on different rows (eg., left third finger 138). On a QWERTY keyboard, twenty percent of all English digraphs are typed by adjacent fingers and more than 4 percent (such as the common ed) are typed by the same finger.

The result of all these shortcomings is that typing on a QWERTY keyboard 100 is tiring, slow, inaccurate and inefficient for the operator or typist. In brief, the QWERTY keyboard did not take the anatomy of the human hand into consideration during its development. Instead, the standard QWERTY keyboard was designed to avoid mechanical problems in early typewriters and ignored ergonomic considerations and cognitive issues for the typist. Due to the growing concern about repetitive stress injuries, or cumulative trauma disorders (CTD) over the past twenty years in relation to typing, the inventor describes a new keyboard that can reduce the incidence of CTD. Although there is a debate as to the best keyboard layouts for human performance (QWERTY vs. Dvorak), the present invention assumes that the pervasiveness of the QWERTY keyboard will remain and any keyboard design will not change any time soon. Furthermore, with advent of touch-typing and miniaturization of computers-type instruments such as laptops, Personal Digital Assistants (PDA), notebooks and cell phones, the conventional keyboard is quickly becoming obsolete. It is therefore an object of the present invention is to ergonomically optimize the conventional keyboard that is still compatible with the conventional QWERTY keyboard layout. This is mainly because the QWERTY layout unfortunately has obtained widespread acceptance and alternatives to the QWERTY layout have failed to achieve any significant success.

For purposes of understanding the present invention, the area-of-movement of each finger is shown in FIG. 2 with an approximate area of movement (dashed box) for each finger 200-290. First, the movement area of the versatile thumbs 124, 134 is quite limited and confined to the lower row of the keyboard 200, 290. Anatomically, the thumbs oppose the rest of the fingers. As such, the thumbs move laterally downwards and therefore have the horizontal flexibility of the fingers. The index (#2) fingers 126, 136 however are unrestricted and unencumbered especially by other fingers. Such freedom provides considerable greater area of movement upwards, downwards and sideways 240, 250. As mentioned previously, the index fingers are also the strongest fingers. In comparison, the middle fingers 128, 138 are restricted and encumbered by both the index fingers 126, 136 and the ring (#4) fingers 130, 140. Their area of movement is significantly less, more rectangular and a considerably longer in length 230, 260. Like the middle fingers, the ring (#4) fingers are restricted and encumbered by the middle 128, 138 and pinky (#5) fingers 132, 142. Their area of movement is however considerably less than the middle fingers given that the ring finger is shorter than the middle finger 220, 270. Like the index fingers, the pinky fingers 132, 142 are unrestricted and unencumbered by other fingers thereby making their area of movement 210, 280 wider than the ring and middle fingers but smaller than the index fingers given their shorter finger length.

The result of all these shortcomings is that typing on a conventional QWERTY keyboard shown in FIG. 1A is tiring, slow, inaccurate and inefficient for the operator or typist. In brief, most conventional keyboards including non-English or foreign keyboards did not take the anatomy of the human hand and fingers into consideration during its development. Due to the growing concern about repetitive stress injuries over the past twenty years caused by typing, it is a related objective of the present invention to reduce the incidence of cumulative trauma disorders (CTD). It will do so by introducing a plurality of embodiments that in combination make a three-dimensional keyboard. An object of the present invention is not to drastically change the QWERTY keyboard but simply improve the keyboard for wider use in modern and smaller computer-type devices.

### BRIEF SUMMARY OF THE INVENTION

The present invention provides a portable and easier to use three-dimensional keyboard for computer-type devices. In a preferred embodiment, the keyboard of the present invention includes smaller character, functional and operational keys in the horizontal plane, select raised keys in the vertical plane and a keyboard that is more ergonomic and easier to use with smaller computer-type devices.

Whereas others have changed the size of the character keys based on their frequency of use, the present invention offers a key size embodiment based on the freedom-of-movement possible for human hands and fingers in the unnatural typing position. More specifically, in one aspect of the invention, a keyboard may consist of a plurality of three different sizes of alphanumeric, operational and function keys. Unlike other referenced key modifications, each key size is based on the their respective finger's freedom or area of movement shown in FIG. 3A. More particularly, the fingers with the most area of movement such as the index and pinky fingers or the “unencumbered” fingers are assigned much smaller keys than a conventional square key. Whereas the width of a conventional key is approximately 2 cm, that of the “index” key of the present invention can be as small as 0.6 cm thereby reducing the size of a conventional key by almost three-fourths. Such “index” keys can be easily manipulated by the stronger and agile index finger because of its unrestricted and unencumbered area of movement on the QWERTY style keyboard.

The next reduced size key in this embodiment are the “encumbered” keys. These keys may be larger than the previously described “index key” (>0.6 cm) but still same or smaller than the size of a conventional key (≦2 cm). This “encumbered” key size may be positioned under the restricted or encumbered fingers such as the middle and ring fingers or used by the weaker pinky fingers. Such a larger “encumbered” key compensates for the restrictive and encumbered position caused by the adjacent fingers. These larger “encumbered” keys may also be easily reached and manipulated by the next strongest and longer middle or ring fingers and provides additional space for the weakest pinky fingers.

The next sized key of the present embodiment in FIG. 3A is the reduced “operational” key. It may be larger than the previously described “encumbered” key (>1.0 cm) and as large as the conventional square key (<2 cm). An “operational” key may be used for the main RETURN/ENTER function key that remains on the right hand side of the keyboard.

The present invention also provides a “thumb-activated” key. It is larger than the previously described “operational” key (>2.0 cm) but smaller than many of the conventional function sized keys. Such “thumb-activated” key can retain the function of the SPACE key but may also replaces the conventional BACKSPACE or DELETE key.

The result of reducing and varying key sizes in the first embodiment is a keyboard that is horizontally scaled to the size of the average human hand. The present invention can reduced a conventional keyboard on an average of 40 cm to about 20 cm in width (FIG. 8). In short, the present embodiment makes a keyboard more ergonomic by reducing its size and reducing the travel distance of the finger tips.

In another embodiment, the present invention may add vertically raised “bumps” or “protrusions” on a select number of keys. Such “key bumps” may be square, rectangular or circular “bumps” raising the height of the particular selected key. Key height may be raised as much as 0.5 mm to 1 cm. As illustrated in FIG. 5B, the “key bump” may be smaller than the key itself and positioned in the middle of the key. A “key bump” may be composed of similar hard plastic of a keyboard but more preferably made of softer rubber to cushion the fingers as it strikes the key. Such “key bumps” of the second embodiment provide several advantages. First, they provide a tactile feeling or touch recognition for the typist or operator to memorize, recognize and feel which character key their finger is resting or striking. Furthermore, such “key bumps” may assist the typist or operator to position their fingers and hands on the home row position and help prevent loss of such position. In addition, a middle finger “key bump” ensures that the middle finger is indeed striking the middle of the top or bottom row as it reaches for another row. Finally, as shown in FIG. 7B the “key bumps” compensate for the varying lengths of the fingers making the keyboard more ergonomic. This embodiment may also assist a blind person position their fingers correctly on such a keyboard.

In the present invention shown in FIG. 3B, another embodiment delegates more responsibility to the under-utilized thumbs of both hands. This embodiment provides two “thumb-activated” keys that can be used for the SPACE key and a newly re-positioned DELETE key. Additionally, two re-positioned “index” SHIFT keys may be positioned next to the SPACE and DELETE keys and can also now be struck by the newly empowered and versatile thumbs. Furthermore, the function keys are assigned to the smaller “index” keys and are re-positioned at the bottom edge of the keyboard. In this embodiment, the operator can easily reach such function keys either with fingers without lifting the hand or perhaps striking them with the thumbs. Such function keys of the present embodiment are reduced and may include essential function keys such as the CURSOR keys, FN (function shift), ALT and OPTION functions.

In brief, all of these embodiments meets the object of the present invention to provide a simple, improved ergonomic keyboard that is portable, easier-to-use, ergonomic and is compatible with the QWERTY style keyboard.

### BRIEF DESCRIPTION OF THE DRAWINGS

FIG. 1A shows a top view of a conventional QWERTY computer keyboard.

FIG. 1B shows both hands in their respective home position on non-ergonomic conventional QWERTY computer keyboard.

FIG. 2 shows the position of hands and fingers in the home typing position on a conventional QWERTY keyboard.

FIG. 3A is a top view of the present invention showing smaller keys in the horizontal plane of the keyboard.

FIG. 3B shows a top view of a keyboard of the present invention with their respective QWERTY characters.

FIG. 4 illustrates a top view of the fingers and both hands resting on the home row position in an improved ergonomic position of the present invention.

FIG. 5A is a top view of the present invention showing raised keys or “key bumps.”

FIG. 5B is a perspective view of the present invention showing details of the “key bump” in both the horizontal and vertical planes making the keyboard embodiment three-dimensional.

FIG. 6A is a top view of the present invention showing the reduced and vertically raised keys embodiments together.

FIG. 6B illustrates a perspective of both hands and respective fingers in a home typing position on a horizontally reduced keyboard with vertically raised keys of the present invention.

FIG. 7A shows how select keys lay in different X, Y, Z three dimensional planes of the present invention.

FIG. 7B shows a perspective view the left hand and its respective fingers in a more ergonomic position offered by the three dimensional planes of the present invention.

FIGS. 8A and 8B show a comparison of the scale and size of the conventional keyboard from FIG. 1 and the present invention from FIG. 6A.

### DETAILED DESCRIPTION OF PREFERRED EMBODIMENTS

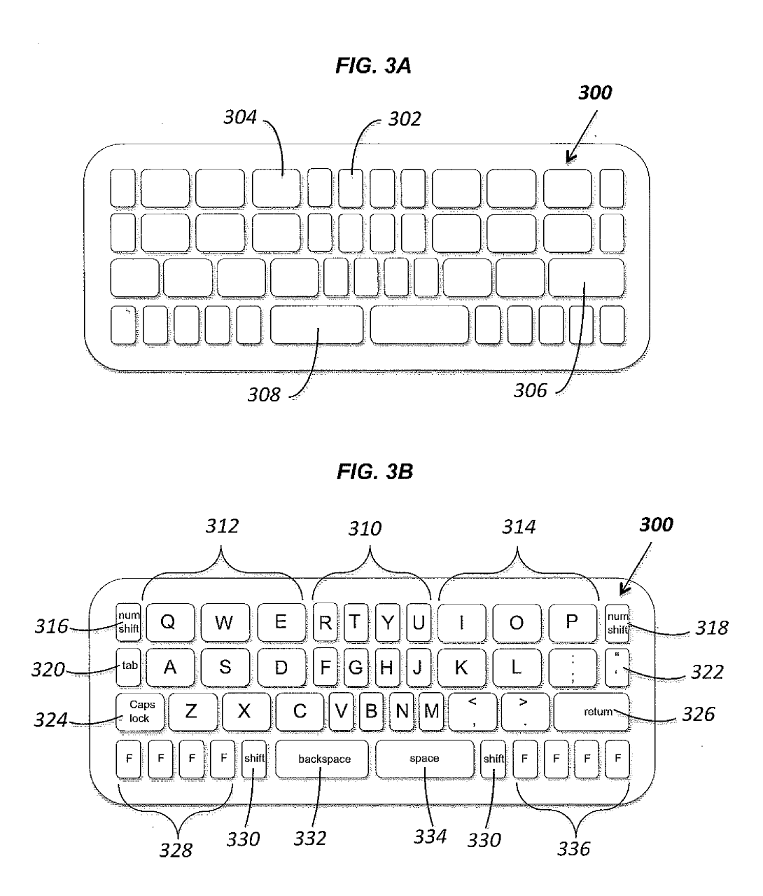

In a preferred embodiment of the present invention, FIG. 3A features a significantly smaller computer-type keyboard 300 with keys varying in size based on the finger's area of movement. The keyboard may, for example, be modeled after the standard and ubiquitous QWERTY keyboard, but modified such that key size is based on their respective hand and finger movement. The preferred keyboard is also reduced to reflect the decreasing size and increasing use of computer-type instruments such as laptops, notebooks, PDA's and mobile phones. Such a keyboard may advantageously increase the overall ease-of-use and portability compared to existing conventional keyboards.

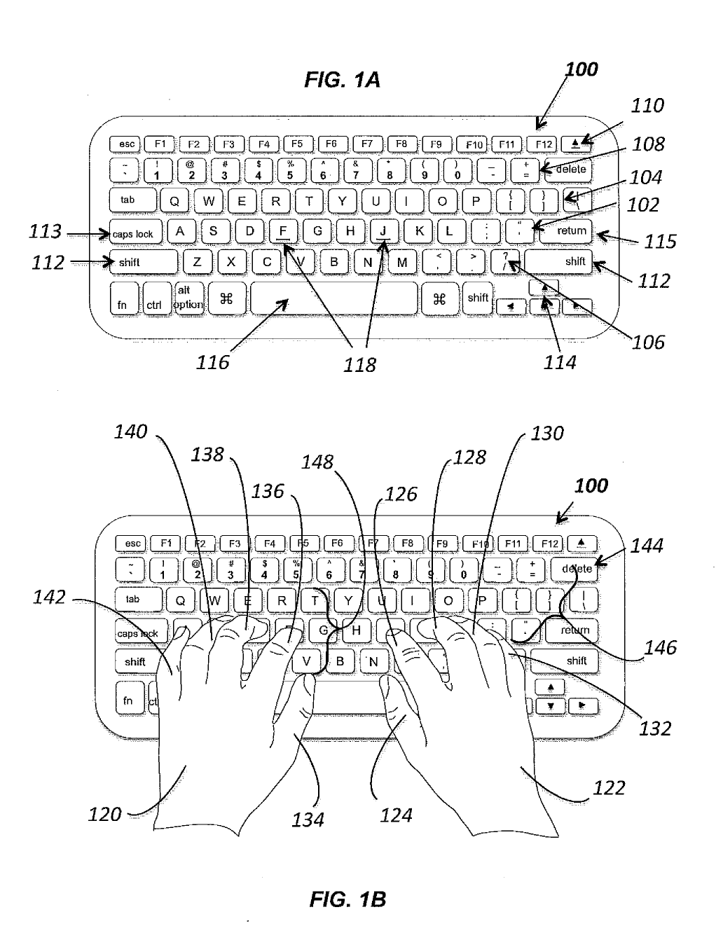

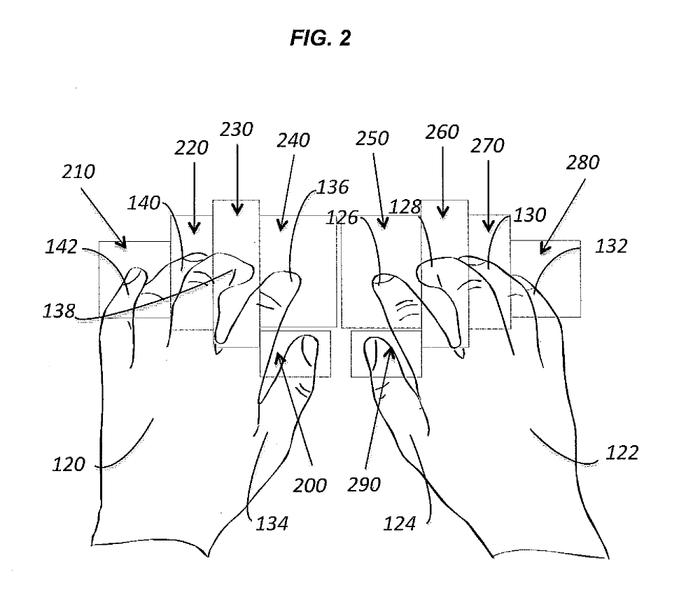

More specifically, in one aspect of the invention, a keyboard is presented in FIG. 3 consist of a plurality of different sized keys. In other words, FIG. 3 shows an embodiment of the present invention with three different sizes of alphanumeric and function keys. Unlike other referenced key modifications, each key size is based on a finger's freedom or area of movement. More particularly, the fingers with the most area of freedom such as the index (#2) finger 126, 136 are assigned much smaller keys 302 than a conventional square key. Whereas the conventional key is approximately 2 cm in width, the “index” key of the present invention can be as small as 0.6 cm. This reduces the conventional square key by almost three-fourths. Such “index” keys 302 can be easily manipulated by the stronger and agile index (#2) finger 126, 136 because of its unrestricted and unencumbered area of movement 240, 250 on the QWERTY keyboard. Under the new arrangement, the cumulative “index” keys can reduce the size of the overall keyboard by at least 4 cm. Please note key drawings between the present invention in FIG. 3 and the conventional keyboard in FIGS. 1 and 2 are not to scale.

The middle sized key 304 of the present invention in FIG. 3A are larger because they are encumbered by fingers on both sides. These keys may be larger than the previously described “index key” 302 (>0.6 cm) but still equal or smaller than the size of a conventional key (≦2 cm). This middle key 304 may be positioned under the restricted or encumbered fingers such as the middle and ring fingers 128, 138, 130, 140 or used by the weaker pinky fingers 132, 142. Such a larger middle key overcomes their restrictive and encumbered position 220, 230, 260, 270 caused by the adjacent index finger 126, 136 next to the middle finger 128, 138, the middle fingers 128, 138 next to the ring fingers 130, 140 or the pinky fingers 132, 142 next the ring fingers 130, 140. Such larger “encumbered” keys may also be easily reached and manipulated by the next strongest and longer middle or ring fingers 128, 138, 130, 140 and provides additional space for the weakest pinky fingers 132, 142.

The larger key 306 of the present invention in FIG. 3A are the operational keys. It is larger than the previously described middle key 304 (>1.0 cm) and as large as the conventional square key (<2 cm). An large key 306 can be used for the main RETURN/ENTER function key that remains on the right hand side of the keyboard.

The largest key 308 of the present invention shown in FIG. 3A are the thumb-activated keys. It is larger than the previously described “operational” key 306 (>2.0 cm) but smaller than many of the conventional space keys. Such “thumb-activated” key on the right hand side can retain the function of the SPACE key but can also replaces the conventional BACKSPACE or DELETE keys on the left hand side.

Now referring to a preferred embodiment, FIG. 3B shows repositioned and different sized keys are matched with respective alphanumeric and functions on an improved keyboard 300 of the present invention. Such an arrangement produces a considerably smaller keyboard in the horizontal plane. For example, the character keys may be arranged with a plurality of “index” keys 302-310 in the middle of the keyboard. This may include the F, G, H, J keys of the home row, the R, T, Y and U of the upper row, and the V, B, N and M keys of the lower row. As previously described, these keys can be struck with minimal movement by the unrestricted and unencumbered stronger and agile index fingers 126, 136 of both hands 120, 122 thereby improving the ability and speed in typing a majority of English digraphs. Furthermore, the minimal movement of the index fingers 126, 136 does not require excessive strain or bending of the wrist which occurs in the conventional keyboard when typing the T, Y, V and B keys.

Another key re-arrangement shown in FIG. 3B may be the use of “encumbered” keys 312, 314 by the middle (#3) fingers 128, 138, ring (44) fingers 130, 140 and/or the pinky (#5) fingers 132, 142. For the left hand 120 these keys 312 may include the A, S and D keys on the home row, the Q, W and E of the top row, and the Z, X and C of the bottom row. For the right hand 122, these keys 314 may include the K, L and :/; keys of the home row, the I, O, and P keys of the top row and the M, <, >. keys of the bottom row. Such larger “encumbered” keys 312, 314 allows the restricted and encumbered fingers 128, 138, 130, 140, 132, 142 more space to move in their respective restricted and encumbered areas of movement 220, 230, 260, 270. Such “encumbered” keys also allow the weaker pinky (#5) fingers 132, 142 have a wider area of movement providing additional space to move away from the restricted and encumbered areas.

FIG. 3B illustrates how the left hand TAB key 320 and the right hand “' character key 322 on the home row can be assigned an “encumbered” key, Furthermore, the NUM SHIFT key on both sides of the keyboard 316, 318 and on the top row can also be “encumbered” keys. Although not shown in the drawings, numeric characters can be embedded onto the top row character keys and activated by pushing the NUM SHIFT keys on both sides of the newly arranged keyboard. The NUM SHIFT can also lock to also function as a NUM LOCK key.

Because of their frequency of use and increasing distance from the home row for the pinky (#5) fingers 132, 142, the CAPS LOCK key 324 and the RETURN key 326 can also be assigned an “encumbered” key 304 and “operational” key 306, respectively.

The bottom row of the keyboard in FIG. 3B reflects the change of the present invention from the conventional keyboard. It delegates more responsibility to the under-utilized thumbs of both hands. A shown in FIG. 3B, two “thumb-activated” keys can be used for the SPACE key 334 and the newly re-positioned BACKSPACE/DELETE key 332. Additionally, two re-positioned “index” SHIFT keys 330 may be positioned next to the SPACE and BACKSPACE/DELETE keys and can also now be struck by the newly empowered and versatile thumbs.

In the present invention shown in FIG. 3B, the conventional function keys are assigned the smaller “index” keys and are re-positioned at the bottom edge of the keyboard 328, 336. On the conventional keyboard, such function keys were at the top edge and in most cases were unreachable unless an operator moved their hands. In the present invention, the operator can easily reach such function keys either with fingers without lifting the hand or perhaps strike them with the thumbs. The function keys of the present invention are reduced and include essential function keys such as the control keys, FN (function shift), ALT, OPTION and cursor functions.

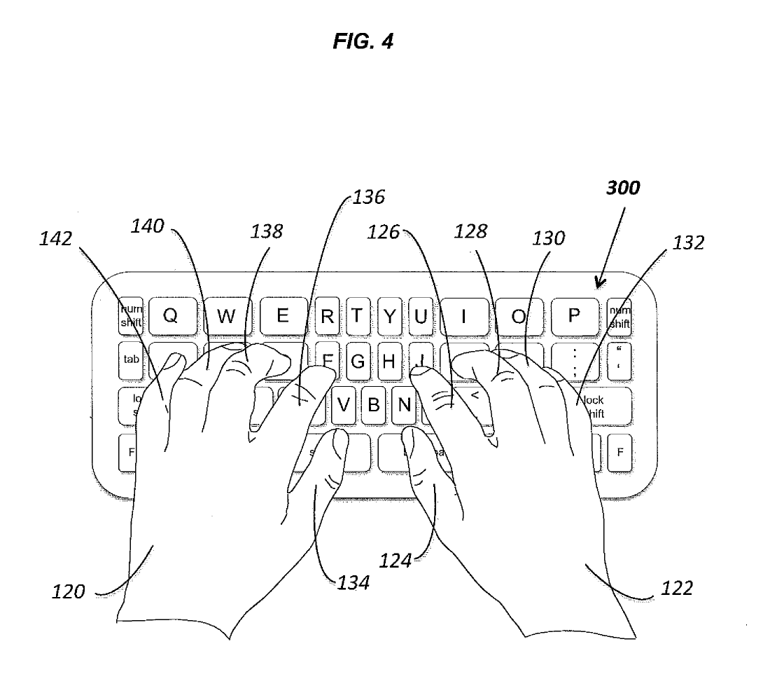

FIG. 4 of the present invention shows how the size of the entire keyboard 300 is horizontally scaled to the size of hands. The “index” keys in middle of the keyboard can now be easily, quickly and readily available to the index fingers 126, 136. The thumbs 124, 134 may be readily available to strike a greater number of keys rather than just striking the one SPACE bar. In the present invention, the thumbs can be directly positioned over the SPACE and BACKSPACE/DELETE keys with easy access to the functions keys. Such thumb-activated keys can also be positioned lower 332, 334 than the other keys because of the lower lateral opposing position of the thumbs 124, 134. Briefly, the present embodiment makes a keyboard more ergonomic by reducing its size.

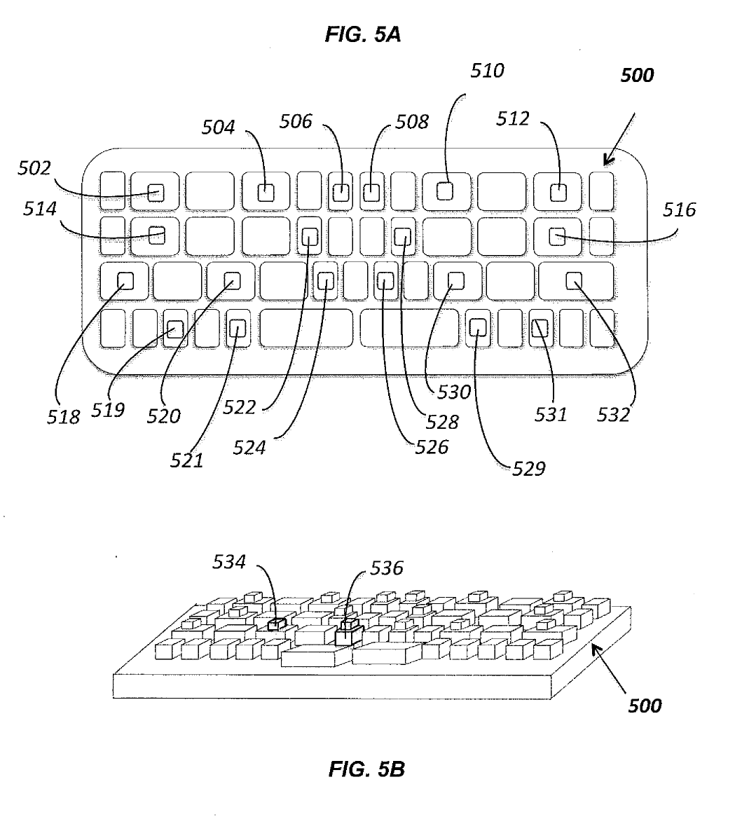

Now that the keys and keyboard are more appropriately sized for smaller or portable computer-type devices, FIG. 5A illustrates another preferred embodiment of the present invention. It is well documented that typing on a QWERTY keyboard is unnecessarily tiring, slow, inaccurate, hard to learn, and particularly hard to remember. For a beginner to reach a speed of 40 words per minute, the person would need 56 hours of training on a QWERTY keyboard but only 18 hours on a Dvorak keyboard. Only a skilled typist with years of experience can reach 75 or more words per minute on a QWERTY keyboard. To do so, one has, to memorize the QWERTY keyboard and not look at the keyboard. In most cases, looking at the keyboard slows the typist and might have to resort to using the “hunt and peck” technique. Most conventional keyboards (FIG. 1) 100 have little or no tactile clues as to where the hand is positioned nor do the fingers have any feedback or feeling as to what key is above it or is pushing (shown in FIG. 1A). Another embodiment 500 of the present invention shown in FIG. 5A introduces a vertical tactile embodiment to the earlier keyboard 300. The present invention adds vertically raised “bumps” or “protrusions” on a select number of keys 502-532.

In preferred embodiments shown in FIG. 5B, such “key bumps” are square, rectangular or circular “bumps” raising the height of the particular selected key. Key height may be raised as much as 0.5 mm to 1 cm. As illustrated, the “key bump” 534 may be smaller than the key itself and positioned in the middle of the key. A “key bump” made be composed of similar hard plastic of a keyboard but more preferably made of softer rubber to cushion the fingers as it strikes the key. Such “key bumps” of the present invention provide several advantages objective. They first provide a tactile feeling or touch recognition for the typist or operator. As such, a typist or operator can now memorize, recognize and feel which character key their finger is resting or striking. Second, such “key bumps” 502-532 may assist the typist or operator to position their fingers and hands on the home row position and easily help prevent loss of such position. Third, a middle finger “key bump” ensures that it is striking the middle of the top or bottom row as it reaches for another row. Additionally, the peripheral “key bumps” 502, 506, 514, 522, 518, 524) struck by the index or pinky fingers of the left hand and “key bumps” 512, 508, 516, 528, 532, 526 struck by the index and pinky fingers of the right hand help tactilely feel the outer edges of its reach. Fourth, they compensate for the varying lengths of the fingers making the key bump keyboard more ergonomic. FIG. 5B also shows how the “key bumps” begin to create a three dimensional keyboard in both the vertical and horizontal planes.

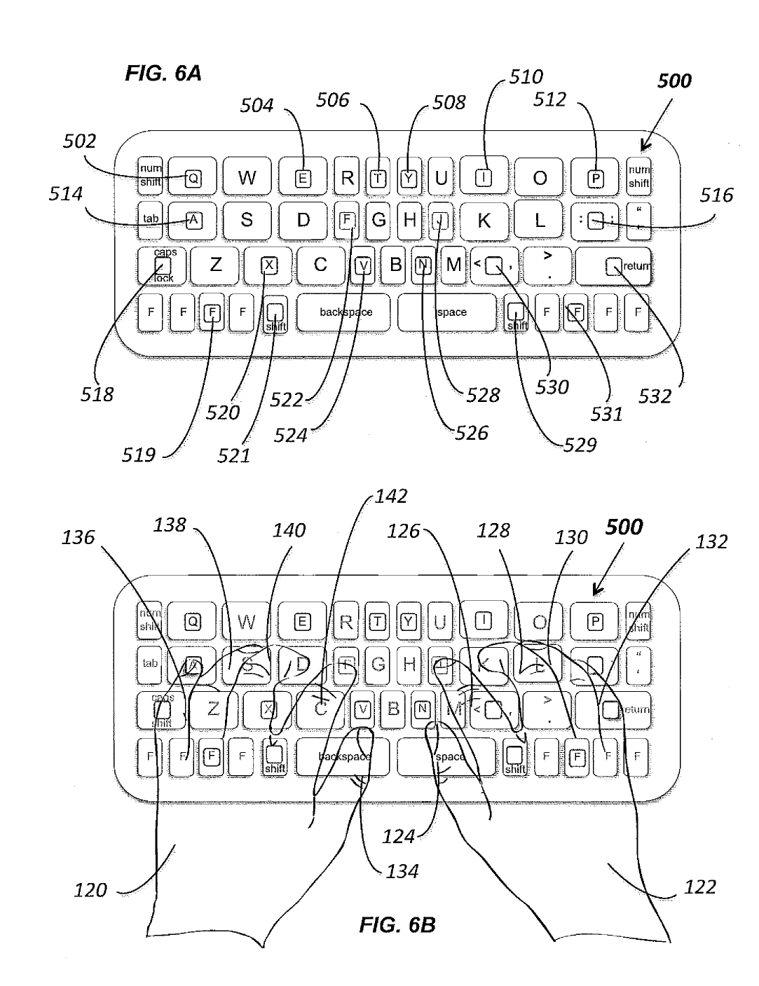

Turning to FIG. 6A, such “bump” keys are assigned their respective vertically raised alphanumeric, operational and functional keys of the earlier preferred horizontal reduced keyboard embodiment 300. Such a new keyboard embodiment 500 consists of vertically raised alphanumeric keys that include the A key 514, F key 522, J key 528 and :; key 516 on the home row; the Q key 502, E key 504, T key 506, Y key 508, I key 510 and P key 512 on the top row; and the CAPS LOCK key 518, X key 520, V key 524, N key 526, <, key 530, and RETURN key 532 on the bottom row.

FIG. 6B illustrates how a plurality of periphery “bump” keys of the present invention can advantageously position the hands 120, 122 at the center of the home, top and bottom rows and simultaneously allow the fingers to tactilely recognize the keys that they are striking. As shown in FIG. 6 the “bump” keys are placed around the periphery of the each hand. Around the left hand are the “bump” A key 514 and F key 522 on the home row; the Q key 502 and T key 506 keys on the top row; and the CAPS LOCK key 518 and V key 524 on the bottom row. For the right hand, the “bump” keys are the J key 528 and :; key 516 on the home row; the Y key 508 and P key 512 keys on the top row; and the N key 526 and RETURN key 532 on the bottom row.

Referring again, FIG. 6B illustrates how a plurality of center “key bumps” 504, 510, 520, 530 of the present invention can ensure that the middle (#3) finger 128 of the right hand and the ring (#4) finger 138 of the left hand do not move the hands and/or fingers off center of each row as it travels to the top and bottom rows. If however the hand or hands moves, the fingers can now tactilely relocated the center “key bump” keys and reposition the hand accordingly. For the left middle (#3) finger, this includes the E key 504 on the top row and the X key 520 on the bottom row. For the right middle (#3) finger, this includes the I key 510 on the top row and the <, key 530 on the bottom row.

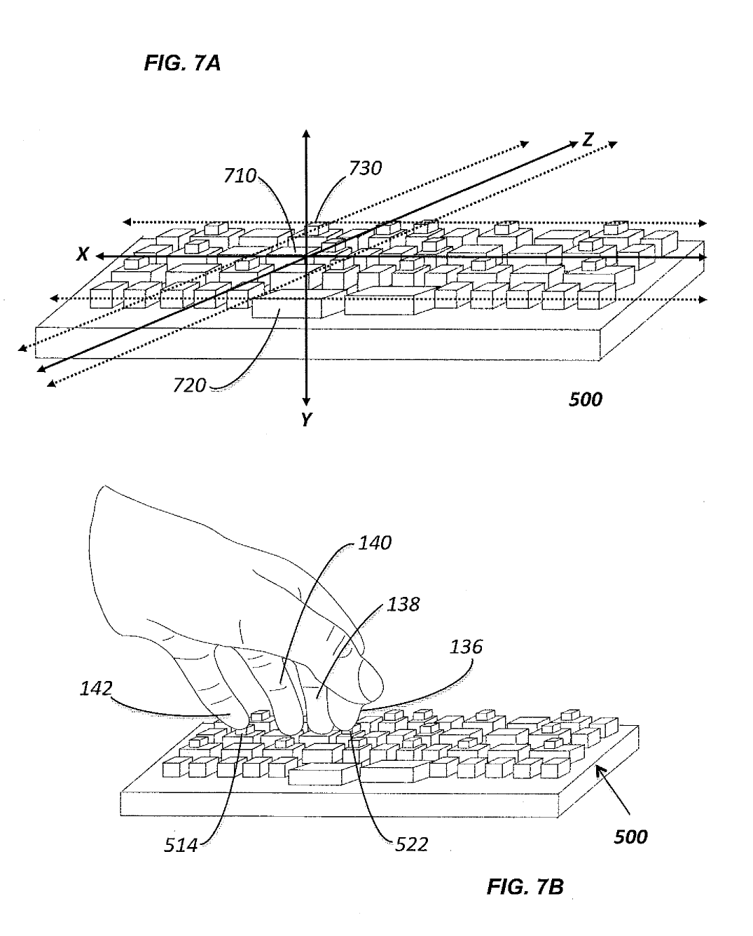

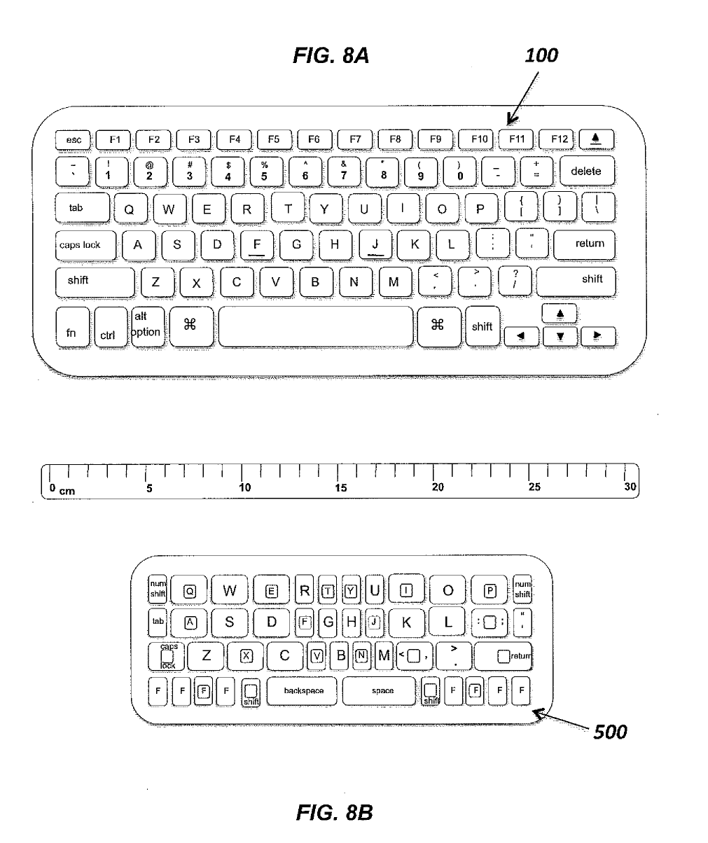

The embodiments of the present invention are shown in FIG. 7A. As the keys change their horizontal and vertical positions, the embodiments of present invention create a three-dimensional keyboard. The horizontally flat or nearly flat conventional keyboard 100 is transformed into a three-dimension keyboard that is more ergonomic for the multi-dimensional human hand.

To illustrate this, FIG. 7A shows how three different keys lie in different planes. The D key 710 sits in the conventional X, Y, Z plane. In contrast, the “key bump” on E key 730 now moves this key to the higher position making it more tactilely recognizable to the “encumbered, the middle finger 138 of the left hand 120. Since twenty percent of all English digraphs are typed by adjacent fingers and more than 4 percent (such as the common keys e & d) are typed by the same finger, the shifting between two planes allows the middle finger to recognize the key it is striking (E key) and helps it return to the home row position (D key).

As for the thumbs, the lower position allows the opposable thumbs to rest in a lower resting position and additionally allows the left thumb 134 and right thumb 124 show in FIG. 6B to alternate between the SPACE 332 and the new BACKSPACE/DELETE 334 keys, respectively.

The improvement in ergonomics of the present invention is shown in FIG. 7B. From an anatomic perspective, the middle (#3) finger 138 and the ring (#4) fingers 140 are longer than the pinky (#5) finger 142 and index (#2) finger 136 of the left hand. In the present invention, the “key bump” A key 514 and F key 522 compensates for this length difference thereby making all of the fingers 136, 138, 140, 142 of the left hand rest in their staggered natural positions instead of the flat position offered by the conventional keyboard shown in FIG. 1B.

In the foregoing specification, the invention has been described with reference to specific preferred embodiments and methods. The QWERTY keyboard is used only as an example for such embodiments of the invention are applicable across many types of conventional keyboard including those used in foreign countries. It will, however, be evident to those of skill in the art that various modifications and changes may be made without departing from the broader spirit and scope of the invention. For example, while horizontal size and vertical heights of the keys has been described for the preferred embodiment to make a more ergonomic keyboard, those of skill in the art will recognize that alternate keys and positions could also be used to accommodate the desired computer-type device. Accordingly, the specification and drawings are to be regarded in an illustrative, rather than restrictive, sense; the invention being limited only by the appended claims.

What is claimed is:

1. An alphanumeric keyboard comprising a plurality of alphanumeric, operational or functional keys of varying sizes wherein said key size correlates to its respective finger's area of movement.

2. The alphanumeric keyboard of claim 1 wherein said alphanumeric, operational or functional keys are a plurality of small, middle and large sizes.

3. The alphanumeric keyboard of claim 1 wherein on said alphanumeric, operational or functional keys are a select number of vertically raised bumps.

4. The alphanumeric keyboard of claim 1 wherein said small keys are struck by the index finger including the TAB, F, G, H, J and “' keys on the home row, the NUM SHIFT, R, T, Y and U of the upper row, the V, B, N and M keys of the lower row and the function (F) keys on the SPACE BAR row.

5. The keyboard of claim 1 wherein said medium size keys include the A, S, D K, L and :/; keys on the home row; the Q, W, E I, O and P of the upper row; and the CAPS LOCK, Z, X, C, M, <,; and >. keys of the lower row.

6. The keyboard of claim 1 wherein said large keys include the RETURN key on the lower row, SPACE and DELETE keys on the SPACE bar row.

7. The keyboard of claim 6 wherein said SPACE and DELETE keys are positioned lower than all other keys and are thumb-activated.

8. The keyboard of claim 1 wherein said vertical bumps are on the A, F, J and :; keys on the home row; the Q, E, T, Y, I and P keys on the upper row; and the CAPS LOCK, X, V, N, < and RETURN keys on the lower row.

9. A method of assembling a three-dimensional keyboard comprising the steps of
constructing a smaller and reduced horizontal keyboard by reducing and varying key size;
placing key bumps to increase vertical key height on select keys;
combining varying key sizes and vertically raised key bumps.
